(19) United States
(12) Patent Application Publication
(10) Pub. No.: US 2019/0211231 A1
(43) Pub. Date: Jul. 11, 2019

(54) ADHESIVE FILM FOR ELECTRIC DEVICE AND METHOD OF FABRICATING SEMICONDUCTOR PACKAGE USING THE SAME

(71) Applicant: ELECTRONICS AND TELECOMMUNICATIONS RESEARCH INSTITUTE, Daejeon (KR)

(72) Inventors: KeonSoo JANG, Daejeon (KR); Yong Sung EOM, Daejeon (KR); Kwang-Seong CHOI, Daejeon (KR); Seok-Hwan MOON, Daejeon (KR); Hyun-cheol BAE, Sejong (KR)

(21) Appl. No.: 16/221,206

(22) Filed: Dec. 14, 2018

(30) Foreign Application Priority Data
Jan. 8, 2018 (KR) 10-2018-0002432
May 10, 2018 (KR) 10-2018-0053710

(51) Int. Cl. C09J 7/30; C09J 167/02; H01L 21/02

(52) U.S. Cl. CPC C09J 7/30; C08G 77/16; H01L 21/02304; C09J 167/02

(57) ABSTRACT

Provided are an adhesive film, and a method of fabricating a semiconductor package using the same. The adhesive film includes a thermoplastic resin containing a hydroxyl group, a thermosetting resin, and an anhydride.

### CROSS-REFERENCE TO RELATED APPLICATIONS

This U.S. non-provisional patent application claims priority under 35 U.S.C. § 119 of Korean Patent Application No. 10-2018-0002432, filed on Jan. 8, 2018, and 10-2018-0053710 filed May 10, 2018, the entire contents of which are hereby incorporated by reference.

### BACKGROUND

The present disclosure herein relates to an adhesive film for an electric device and a method of fabricating a semiconductor package using the same.

In a semiconductor package field, a wire bonding method using a wire, or a flip-chip boding method using a solder ball is applied to mount a semiconductor chip on a package substrate. As one modification of the flip-chip bonding method, there is a method for obtaining electrical connection and adhesive force by using a non-conductive adhesive material or an anisotropic conductive adhesive material and using a solder as a medium. By applying pressure and heat while a non-conductive adhesive material or an anisotropic conductive adhesive material being interposed between a package substrate and a semiconductor chip, the semiconductor chip can be mounted on the package substrate.

### SUMMARY

The present disclosure provides an adhesive film which has a flux function and is easy to manufacture.

The present disclosure also provides a method for manufacturing a semiconductor package having improved reliability.

An embodiment of the inventive concept provides an adhesive film including a thermoplastic resin containing a hydroxyl group, a thermosetting resin, and an anhydride.

In an embodiment, the thermoplastic resin may be included in an amount of 20-70 wt %, and the anhydride may be included in an amount of 1-70 wt %.

In an embodiment, the thermoplastic resin containing a hydroxyl group may be at least one selected from polyethylene oxide, polyvinyl alcohol, phenoxy resin, polyacrylic acid, or polyethylacrylic acid. Alternatively, the thermoplastic resin containing a hydroxyl group may be at least one polymer which is selected from polystyrene, polymethyl methacrylate, polyethylene terephthalate, polyisobutyl methacrylate, polyvinyl pyridine, polycaprolactone, polybutadiene, polydimethylsiloxane, polyisobutylene, polyisopropene, polycarbonate, polypropylene, polyethylene, or polyvinyl chloride and whose terminal or main chain may be substituted by a hydroxyl group.

In an embodiment, the thermosetting resin may be at least one selected from maleimide, epoxy, phenoxy, bismaleimide, unsaturated polyester, urethane, urea, phenol-formaldehyde, vulcanized rubber, melamine resin, polyimide, epoxy novolak resin, or cyanate ester.

In an embodiment, the anhydride may be at least one selected from nadic maleic anhydride, dodecyl succinic anhydride, maleic anhydride, succinic anhydride, methyl tetrahydro phthalic anhydride, hexahydro phthalic anhydride, tetrahydro phthalic anhydride, pyromellitic anhydride, cyclohexanedicarboxylic anhydride, 1,2,4-benzenetricarboxylic anhydride, or benzophenone-3,3′,4,4′-tetracarboxylic dianhydride.

In an embodiment, the adhesive film may further include an insulating filler, and the insulating filler may be included in an amount of 0-90 wt % with respect to the combined weight of the thermoplastic resin containing a hydroxyl group, the thermosetting resin, and the anhydride.

In an embodiment, the insulating filler may be at least one selected from silica, barium sulfate, alumina, clay, kaolin, talc, manganese oxide, zinc oxide, calcium carbonate, titanium oxide, mica, wollastonite, or basalt.

In an embodiment of the inventive concept, a method of fabricating a semiconductor package includes preparing an adhesive film, placing the adhesive film on a package substrate including a conductive pad, placing, on the adhesive film, a semiconductor chip with a solder ball attached thereto, and performing a heating process to attach the solder ball to the conductive pad and to cure the adhesive film.

In an embodiment, the preparing of the adhesive film may include preparing an adhesive composition including a thermoplastic resin containing a hydroxyl group, a thermosetting resin, an anhydride, and an organic solvent, coating a release film with the adhesive composition, removing the organic solvent, and removing the release film.

In an embodiment, the heating process may be performed at a temperature of 100-300° C.

### BRIEF DESCRIPTION OF THE FIGURES

The accompanying drawings are included to provide a further understanding of the inventive concept, and are incorporated in and constitute a part of this specification.

The drawings illustrate exemplary embodiments of the inventive concept and, together with the description, serve to explain principles of the inventive concept. In the drawings:

FIGS. 1A to 1C are process cross-sectional views showing a process for preparing an adhesive film according to embodiments of the inventive concept;

FIGS. 2 to 4 are cross-sectional views sequentially showing a method for fabricating a semiconductor package according to the inventive concept;

FIG. 5 is a graph showing the results of NMR analysis by heating the adhesive film according to Preparation Example 1 of the inventive concept;

FIG. 6 is a graph showing glass transition temperature and Young's modulus of an underfill formed by heating the adhesive film according to Preparation Example 1 of the inventive concept, and an underfill formed by heating a typical adhesive film; and

FIG. 7 is an SEM photograph showing a cross section of a portion of a semiconductor package fabricated using the adhesive film according to Preparation Example 1 of the inventive concept.

### DETAILED DESCRIPTION

Hereinafter, exemplary embodiments according to the inventive concept will be described in more detail with reference to the accompanying drawings in order to explain the inventive concept more specifically.

Objects, other objects, features, and advantages of the inventive concept will be readily understood through the following preferred exemplary embodiments with reference to the accompanying drawings. However, the inventive concept is not limited to the exemplary embodiments described herein but may be embodied in other forms. Rather, the exemplary embodiments disclosed herein are provided so that the disclosure will be thorough and complete, and will fully convey the scope of the inventive concept to those skilled in the art.

In the present specification, when an element is referred to as being on another element, it may mean that the element is directly formed on another element or it may mean that a third element may be interposed therebetween. In addition, in the drawings, the thickness of components is exaggerated for an effective description of technical content.

Exemplary embodiments described herein will be described with reference to cross-sectional views and/or plan views which are ideal illustrations of the inventive concept. In the drawings, the thicknesses of the films and regions are exaggerated for an effective explanation of technical content. Accordingly, the shape of an illustration may be modified by manufacturing techniques and/or tolerances. Accordingly, exemplary embodiments of the inventive concept are not limited to the specific forms shown, but also include changes in the forms generated according to a manufacturing process. For example, an etching region shown at right angle may be rounded or may be in a shape having a predetermined curvature. Therefore, regions illustrated in the drawings have properties, and the shapes of the regions illustrated in the drawings are intended to illustrate specific forms of regions of an element, and are not intended to limit the scope of the inventive concept.

Although the terms first, second, and the like are used to describe various components in various exemplary embodiments of the present specification, these components should not be limited by these terms. These terms are only used to distinguish one element from another. The exemplary embodiments described and illustrated herein also include complementary exemplary embodiments thereof.

The terminology used herein is for the purpose of describing exemplary embodiments and is not intended to be limiting of the inventive concept. In the present specification, terms of a singular form may include terms of a plural form unless the context clearly indicates otherwise. As used herein, the terms “comprises” and/or “comprising” do not exclude the presence or addition of one or more other elements.

Hereinafter, exemplary embodiments of the inventive concept will be described in detail with reference to the accompanying drawings.

An adhesive film according to the inventive concept includes a thermoplastic resin containing a hydroxyl group (OH—); a thermosetting resin; and an anhydride. The thermoplastic resin may be included in an amount of 20-70 wt %, and the anhydride may be included in an amount of 1-70 wt %. The thermosetting resin may be included in an amount of 10-79 wt %.

The thermoplastic resin containing a hydroxyl group is a polymer containing a hydroxyl group itself, and may be, for example, at least one selected from polyethylene oxide, polyvinyl alcohol, phenoxy resin, polyacrylic acid, or polyethylacrylic acid. The repeating unit (n) of the thermoplastic resin is preferably 10-10,000.

Alternatively, in the thermoplastic resin containing a hydroxyl group, hydrogen present in a terminal or main chain of the thermoplastic resin may be substituted with a hydroxyl group. Specifically, the thermoplastic resin containing a hydroxyl group may be at least one polymer which is selected from hydrogen present in the terminal or main chain of at least one polymer selected from polystyrene, polymethylacrylate, polyethylene terephthalate, polyisobutyl methacrylate, polyvinyl pyridine, polycaprolactone, polybutadiene, polydimethylsiloxane, polyisobutylene, polyisopropene, polycarbonate, polypropylene, polyethylene, or polyvinyl chloride and whose terminal or main chain is substituted by a hydroxyl group.

Thermosetting resin monomers having a molecular weight of 50-1000 g/mol may be used as the thermosetting resin. The thermosetting resin may be preferably cured at 100-300° C. The thermosetting resin may be, for example, at least one selected from maleimide, epoxy, phenoxy, bismaleimide, unsaturated polyester, urethane, urea, phenol-formaldehyde, vulcanized rubber, melamine resin, polyimide, epoxy novolak resin, or cyanate ester.

The anhydride may be at least one selected from nadic maleic anhydride, dodecyl succinic anhydride, maleic anhydride, succinic anhydride, methyl tetrahydro phthalic anhydride, hexahydro phthalic anhydride, tetrahydro phthalic anhydride, pyromellitic anhydride, cyclohexanedicarboxylic anhydride, 1,2,4-benzenetricarboxylic anhydride, or benzophenone-3,3′,4,4′-tetracarboxylic dianhydride.

The adhesive film may further include an insulating filler to improve the mechanical properties thereof. The adhesive film may be included in an amount of 0-90 wt % with respect to the combined weight of the thermoplastic resin containing a hydroxyl group, the thermosetting resin, and the anhydride.

The insulating filler may be at least one selected from silica, barium sulfate, alumina, clay, kaolin, talc, manganese oxide, zinc oxide, calcium carbonate, titanium oxide, mica, wollastonite, and basalt.

A process for preparing the adhesive film may include preparing an adhesive composition including a thermoplastic resin containing a hydroxyl group, a thermosetting resin, an anhydride, and an organic solvent, coating a release film with the adhesive composition, removing the organic solvent, and removing the release film.

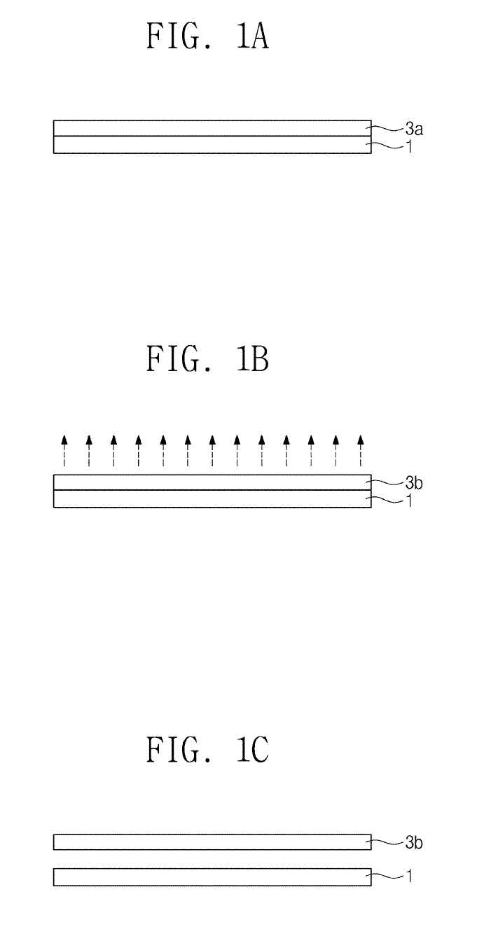

FIGS. 1A to 1C are process cross-sectional views showing a process for preparing an adhesive film according to embodiments of the inventive concept;

Referring to FIG. 1A, an adhesive composition 3A is coated on a release film 1. The adhesive composition 3A may be prepared by mixing the thermoplastic resin containing a hydroxyl group, the thermosetting resin, and the anhydride, which are described above, in an organic solvent. The thermoplastic resin containing a hydroxyl group, the thermosetting resin, and the anhydride may be dissolved in the organic solvent. The organic solvent may be, for example, at least one of tetrahydrofuran (THF), chloroform, methylene chloride, methanol, ethanol, butanol, pentanol, propanol, acetone, benzene, toluene, and diethyl ether. The insulating filler described above may be further added to the adhesive composition 3A.

Referring to FIGS. 1A and 1B, the adhesive composition 3A is coated on the release film 1, and then the organic solvent contained in the adhesive composition 3A may be evaporated/volatilized. The process may be performed, for example, at room temperature. An adhesive film 3B may be formed thereby.

Referring to FIG. 1C, the release film 1 may be separated from the adhesive film 3B. The adhesive film 3B may be obtained thereby.

Next, specific preparation examples will be described.

### Preparation Example 1

In Preparation Example 1, the thermoplastic resin containing a hydroxyl group may be polydimethylsiloxane substituted with a hydroxyl group, the thermosetting resin may be maleimide, and the anhydride may be succinic anhydride. THF may be used as an organic solvent and mixed therewith to form a film composition. At this time, the maleimide and the succinic anhydride may be included in a stoichiometric ratio of 1:0.1 to 1:5.0, and the polydimethylsiloxane substituted with a hydroxyl group may be included in an amount of 30-300 phr based on the weight of the thermosetting resin. In addition, barium sulfate may be additionally added thereto in an amount of 0-90 wt % as an insulating filler. The film composition thus prepared is thinly applied on a release film, and left at room temperature to evaporate the organic solvent, thereby preparing an adhesive film.

### Preparation Example 2

In Preparation Example 2, the thermoplastic resin containing a hydroxyl group may be polyvinyl alcohol, the thermosetting resin may be epoxy, and the anhydride may be maleic anhydride. THF may be used as an organic solvent and mixed therewith to form a film composition. At this time, the epoxy and the maleic anhydride may be included in a stoichiometric ratio of 1:0.2 to 1:7.0, and the polyvinyl alcohol may be included in an amount of 20-300 phr based on the weight of the thermosetting resin. In addition, silica may be additionally added thereto in an amount of 0-90 wt % as an insulating filler. The film composition thus prepared is thinly applied on a release film, and left at room temperature to evaporate the organic solvent, thereby preparing an adhesive film.

### Preparation Example 3

In Preparation Example 3, the thermoplastic resin containing a hydroxyl group may be polyethylene terephthalate substituted with a hydroxyl group, the thermosetting resin may be phenol-formaldehyde, and the anhydride may be dodecylsuccinic anhydride. At this time, the phenol-formaldehyde and the dodecylsuccinic anhydride may be included in a stoichiometric ratio of 1:0.1 to 1:8.0, and the polyethylene terephthalate substituted with a hydroxyl group may be included in an amount of 20-300 phr based on the weight of the thermosetting resin. In addition, barium sulfate may be additionally added thereto in an amount of 0-90 wt % as an insulating filler. The film composition thus prepared is thinly applied on a release film, and left at room temperature to evaporate the organic solvent, thereby preparing an adhesive film.

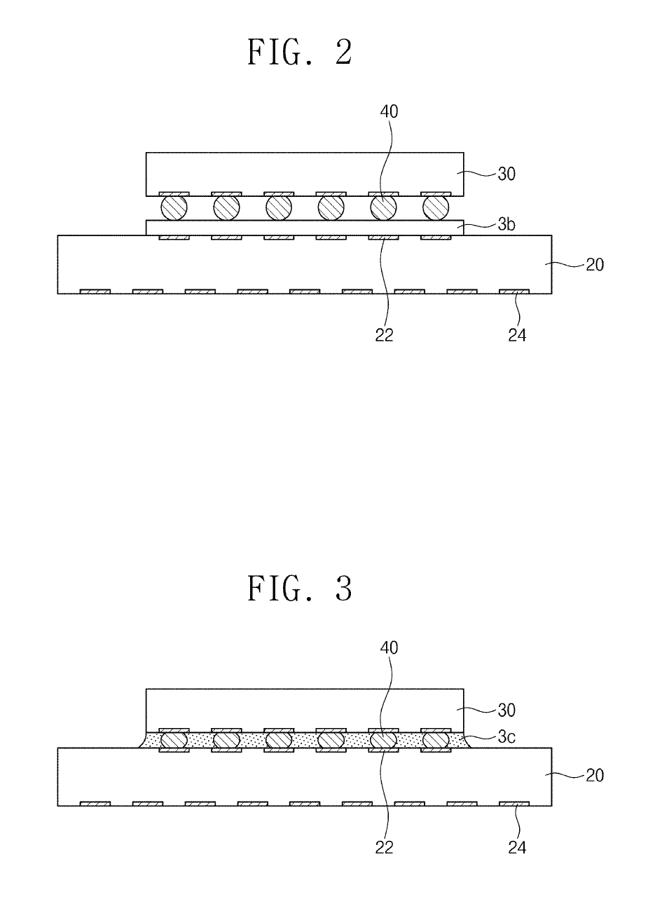

FIGS. 2 to 4 are cross-sectional views sequentially showing a method for fabricating a semiconductor package according to the inventive concept.

Referring to FIG. 2, a package substrate 20 may be prepared. The package substrate 20 may include upper conductive patterns 22 disposed on an upper surface thereof and lower conductive patterns 24 disposed on a lower surface thereof. On the upper surface of the package substrate 20, the adhesive film 3B prepared with reference to FIGS. 1A to 1C may be placed. On the adhesive film 3B, a semiconductor chip 30 attached with first solder balls 40 may be placed.

Referring to FIG. 3, a heating process may be performed to attach the first solder balls 40 to the upper conductive patterns 22 and to cure the adhesive film 3B, thereby forming an underfill 3C. The heating process may be performed at a temperature of 100-300° C. By the heating process, following chemical reactions may occur in the adhesive film 3B.

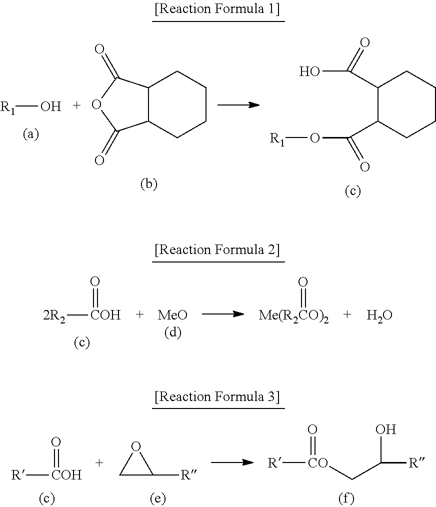

In Reaction Formula 1, cyclohexanedicarboxylic anhydride (b) is exemplified as the anhydride. Referring to Reaction Formula 1, by the heating process, the thermoplastic resin containing a hydroxyl group (a) reacts with the anhydride (b) to form an acid to which a carboxyl group (—COOH) is bonded. The acid (c) thus formed may react with a metal oxide layer (d) on the surfaces of the first solder balls 40 and the upper conductive patterns 22 to remove the metal oxide layer (d) as shown in Reaction Formula 2. That is, in the adhesive film 3B, the thermoplastic resin containing a hydroxyl group (a) may react with the anhydride (b) to function as a flux. In addition, the acid (c) formed in Reaction Formula 1 may react with an epoxy to form a macro-monomer (f) as shown in Reaction Formula 3. A thermoplastic resin containing a hydroxyl group according to the inventive concept may function as a matrix in the curing reaction or in the underfill 3C finally formed. As a result, the mechanical, chemical, and thermal properties of the underfill 3c finally formed may become more excellent, so that the reliability of the semiconductor package may be improved.

As the size of a semiconductor package become smaller, it is not suitable to use a non-conductive adhesive material or an anisotropic conductive adhesive material as a paste type since it is difficult to accurately control the amount to be used and position thereof. However, since an adhesive film is used in an embodiment of the inventive concept, it is easy to accurately adjust the amount to be used and position thereof. In addition, an adhesive film of the inventive concept has a flux function, so that a typical complicated process in which a flux agent is applied in advance to remove an oxide film and then a cleaning process is performed may be omitted. Accordingly, a process of fabricating a semiconductor package may be simplified by using the adhesive film of the inventive concept.

In addition, the adhesive film according to the inventive concept may exclude a flux agent. In the inventive concept, since a thermoplastic resin may function as a flux by including a hydroxyl group, there is no need to add a separate low molecular flux agent. Therefore, a preparation process of an adhesive film is simpler. In addition, since a separate low molecular flux agent is not included, it is possible to prevent a low molecular flux agent from lowering the molecular weight in an underfill, or deteriorating the mechanical, chemical, and thermal properties thereof.

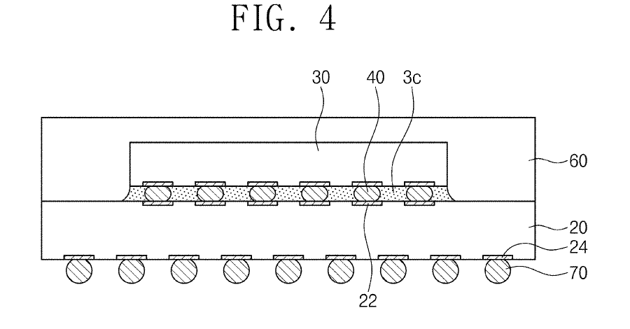

Referring to FIG. 4, a mold film 60 covering the semiconductor chip 30 and the package substrate 20 may be formed subsequently. The mold film 60 may include an epoxy molding compound (EMC). In addition, second solder balls 70 may be attached to the lower conductive patterns 24 of the package substrate 20.

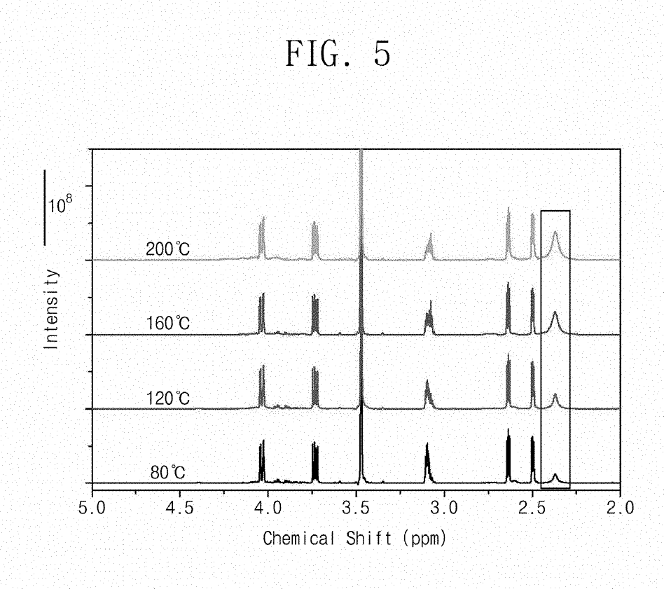

FIG. 5 is a graph showing the results of NMR analysis by heating the adhesive film according to Preparation Example 1 of the inventive concept. Referring to FIG. 5, it can be seen that an acid was detected at 2.37 ppm. In addition, it can be seen that as heating temperature was increased from 80° C. to 200° C., the strength of the acid was strong at 2.37 ppm. As a result, it can be seen that the detection amount of the acid increased as the heating temperature was increased.

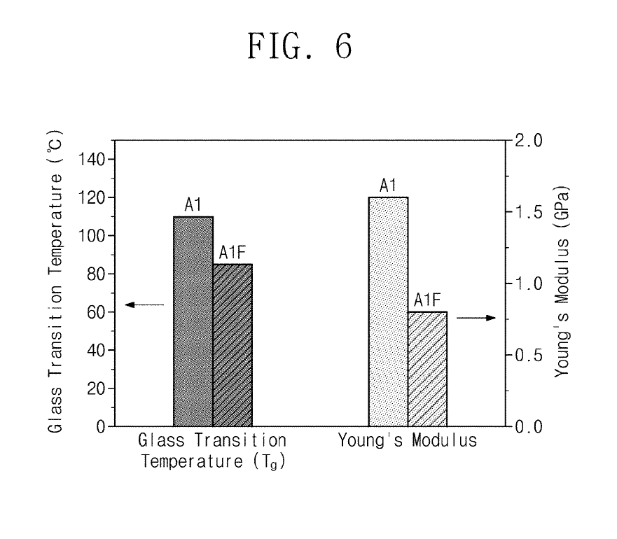

FIG. 6 is a graph showing glass transition temperature and Young's modulus of an underfill A1 formed by heating the adhesive film according to Preparation Example 1 of the inventive concept, and an underfill A1F formed by heating a typical adhesive film. The typical adhesive film may not include the thermoplastic resin containing a hydroxyl group of the inventive concept, but may include a thermosetting resin, a thermosetting agent, and a low molecular flux agent. Referring to FIG. 6, it can be seen that the glass transition temperature and Young's modulus of the underfill A1 formed by heating the adhesive film according to Production Example 1 of the inventive concept are higher than those of the underfill A1F formed by heating the typical adhesive film. As a result, it can be seen that the mechanical, chemical, and thermal properties of the underfill formed using the adhesive film of the inventive concept are further improved.

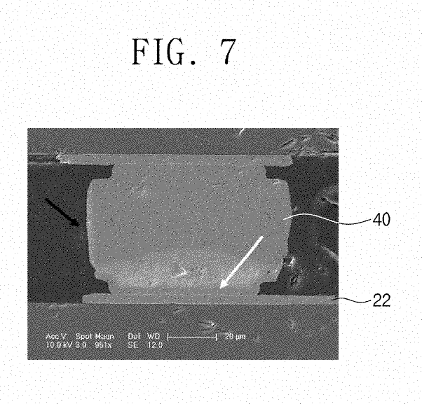

FIG. 7 is an SEM photograph showing a cross section of a portion of a semiconductor package fabricated using the adhesive film according to Preparation Example 1 of the inventive concept. Referring to FIG. 7, when looking at the areas marked with arrows, it can be seen that there is no oxide film on a surface of a first solder ball 40 or on an interface between an upper conductive pattern 22 and the first solder ball 40. As a result, it can be seen that complete wetting between the first solder ball 40 and the upper conductive pattern 22 has been achieved.

An adhesive film according to embodiments of the inventive concept may function as a flux. In addition, the mechanical, chemical, and thermal properties of an underfill formed by curing the adhesive film may become more excellent, so that the reliability of a semiconductor package may be improved.

In addition, since an adhesive film according to embodiments of the inventive concept does not include a separate low molecular flux agent, a preparation process of the adhesive film may be simplified and limitations caused by the use of the low molecular flux agent may be solved at the same time.

A method of fabricating a semiconductor package according to embodiments of the inventive concept uses the adhesive film so that a package process may be precisely controlled and a fabrication process may be simplified.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. An adhesive film comprising:
a thermoplastic resin containing a hydroxyl group;
a thermosetting resin; and
an anhydride.

2. The adhesive film of claim 1, wherein the thermoplastic resin is included in an amount of 20-70 wt %, and the anhydride is included in an amount of 1-70 wt %.

3. The adhesive film of claim 1, wherein the thermoplastic resin containing a hydroxyl group is at least one selected from polyethylene oxide, polyvinyl alcohol, phenoxy resin, polyacrylic acid, or polyethylacrylic acid.

4. The adhesive film of claim 1, wherein the thermoplastic resin is at least one polymer which is selected from polystyrene, polymethyl methacrylate, polyethylene terephthalate, polyisobutyl methacrylate, polyvinyl pyridine, polycaprolactone, polybutadiene, polydimethylsiloxane, polyisobutylene, polyisopropene, polycarbonate, polypropylene, polyethylene, or polyvinyl chloride and whose terminal or main chain is substituted by a hydroxyl group.

5. The adhesive film of claim 1, wherein the thermosetting resin is at least one selected from maleimide, epoxy, phenoxy, bismaleimide, unsaturated polyester, urethane, urea, phenol-formaldehyde, vulcanized rubber, melamine resin, polyimide, epoxy novolak resin, or cyanate ester.

6. The adhesive film of claim 1, wherein the anhydride is at least one selected from nadic maleic anhydride, dodecyl succinic anhydride, maleic anhydride, succinic anhydride, methyl tetrahydro phthalic anhydride, hexahydro phthalic anhydride, tetrahydro phthalic anhydride, pyromellitic anhydride, cyclohexanedicarboxylic anhydride, 1,2,4-benzenetricarboxylic anhydride, or benzophenone-3,3′,4,4′-tetracarboxylic dianhydride.

7. The adhesive film of claim 1, further comprising an insulating filler, wherein the insulating filler is included in an amount of 0-90 wt % with respect to the combined weight of the anhydride, the thermosetting resin, and the thermoplastic resin containing a hydroxyl group.

8. The adhesive film of claim 7, wherein the insulating filler is at least one selected from silica, barium sulfate, alumina, clay, kaolin, talc, manganese oxide, zinc oxide, calcium carbonate, titanium oxide, mica, wollastonite, or basalt.

9. The adhesive film of claim 1, wherein the thermoplastic resin containing a hydroxyl group is polydimethylsiloxane substituted with a hydroxyl group; the thermosetting resin is maleimide; and the anhydride is succinic anhydride, wherein the maleimide and the succinic anhydride are included in a stoichiometric ratio of 1:0.1 to 1:5.0, and the polydimethylsiloxane substituted with a hydroxyl group is included in an amount of 30-300 phr.

10. The adhesive film of claim 1, wherein the thermoplastic resin containing a hydroxyl group is polyvinyl alcohol; the thermosetting resin is epoxy; and the anhydride is maleic anhydride, wherein the epoxy and the maleic anhydride are included in a stoichiometric ratio of 1:0.2 to 1:7.0, and the polyvinyl alcohol is included in an amount of 20-300 phr.

11. The adhesive film of claim 1, wherein the thermoplastic resin containing a hydroxyl group is polyethylene terephthalate substituted with a hydroxyl group; the thermosetting resin is phenol-formaldehyde; and the anhydride is dodecyl succinic anhydride, wherein the phenol-formaldehyde and the dodecyl succinic anhydride are included in a stoichiometric ratio of 1:0.1 to 1:8.0, and the polyethylene terephthalate substituted with a hydroxyl group is included in an amount of 20-300 phr.

12. A method of fabricating a semiconductor package, comprising:
preparing an adhesive film;
placing the adhesive film on a package substrate including a conductive pad;
placing, on the adhesive film, a semiconductor chip with a solder ball attached thereto; and
performing a heating process to attach the solder ball to the conductive pad and to cure the adhesive film.

13. The method of claim 12, wherein the preparing of the adhesive film comprises:
preparing an adhesive composition including a thermoplastic resin containing a hydroxyl group, a thermosetting resin, an anhydride, and an organic solvent;
coating a release film with the adhesive composition;
removing the organic solvent; and
removing the release film.

14. The method of claim 13, wherein after the removing of the organic solvent, the thermoplastic resin is included in the adhesive film in an amount of 20-70 wt %, and the anhydride is included in the adhesive film in an amount of 1-70 wt %.

15. The method of claim 13, wherein the thermoplastic resin containing a hydroxyl group is at least one selected from polyethylene oxide, polyvinyl alcohol, phenoxy resin, polyacrylic acid, or polyethylacrylic acid.

16. The method of claim 13, wherein, the thermoplastic resin containing a hydroxyl group is at least one polymer which is selected from polystyrene, polymethyl methacrylate, polyethylene terephthalate, polyisobutyl methacrylate, polyvinyl pyridine, polycaprolactone, polybutadiene, polydimethylsiloxane, polyisobutylene, polyisopropene, polycarbonate, polypropylene, polyethylene, or polyvinyl chloride and whose terminal or main chain is substituted by a hydroxyl group.

17. The method of claim 13, wherein the thermosetting resin is at least one selected from epoxy, phenoxy, bismaleimide, unsaturated polyester, urethane, urea, phenol-formaldehyde, vulcanized rubber, melamine resin, polyimide, epoxy novolak resin, or cyanate ester.

18. The method of claim 13, wherein the anhydride is at least one selected from nadic maleic anhydride, dodecyl succinic anhydride, maleic anhydride, succinic anhydride, methyl tetrahydro phthalic anhydride, hexahydro phthalic anhydride, tetrahydro phthalic anhydride, pyromellitic anhydride, cyclohexanedicarboxylic anhydride, 1,2,4-benzenetricarboxylic anhydride, or benzophenone-3,3′,4,4′-tetracarboxylic dianhydride.

19. The method of claim 13, wherein the adhesive composition further comprises an insulating filler, and the insulating filler is included in an amount of 0-90 wt % with respect to the combined weight of the thermoplastic resin containing a hydroxyl group, the thermosetting resin, and the anhydride.

20. The method of claim 12, wherein the heating process is performed at a temperature of 100-300° C.
